(19) United States
(12) Patent Application Publication
(10) Pub. No.: US 2026/0086126 A1
(43) Pub. Date: Mar. 26, 2026

(54) ELECTROMAGNETIC ENERGY CHARGING CLAMP METER

(71) Applicant: 3EGREEN TECHNOLOGY, INC., New Taipei City (TW)

(72) Inventors: Huang-Liang Wang, New Taipei City (TW); Jen-Tso Wu, New Taipei City (TW)

(21) Appl. No.: 19/334,957

(22) Filed: Sep. 21, 2025

(30) Foreign Application Priority Data
Sep. 24, 2024 (TW) 113210348

(51) Int. Cl. G01R 15/18; G01R 19/22

(52) U.S. Cl. CPC G01R 15/186; G01R 19/22

(57) ABSTRACT

An electromagnetic energy charging clamp meter includes an electromagnetic induction unit respectively connected to a test wire and an automatic switching unit. A two-stage gear switching unit is connected to the measurement terminal of the automatic switching unit and has a low-range measurement and a high-range measurement. An AC/DC conversion unit is connected to the two-stage gear switching unit. A microprocessor calculation unit is connected to the AC/DC conversion unit and has a charging control output device and a measurement control output device. The charging control output device is connected to the automatic switching unit. The measurement control output device is connected to the two-stage gear switching unit. A rectification unit is connected to the charging terminal of the automatic switching unit. An energy storage unit is connected to the rectification unit. A rechargeable battery is connected to the charging unit to provide power to the microprocessor calculation unit.

### BACKGROUND OF THE UTILITY MODEL

### 1. Fields of the utility model

The present utility model relates to the technical field of measuring current magnitude in test wires, and more particularly, to an electromagnetic energy charging clamp meter.

### 2. Descriptions of Related Art

Electricity is one of the indispensable energy sources today, and electricity can be divided into two types: alternating current (AC) and direct current (DC). Direct current is common in many extra-low voltage and low voltage devices, mostly applied in various electronic instruments, electrolysis, electroplating, DC power drives, and other aspects. When measuring direct current nowadays, most professionals use multimeters for testing. Common tools include sensitive galvanometers (G meters), ammeters, voltmeters, bridges, and potentiometers. With advancements in technology, digital clamp meters have become the most commonly used measuring tools for most professionals and maintenance personnel.

For existing current clamp meters, when current flows through the wire being tested, it generates an electromagnetic field. The wire being tested can then generate induced current through electromagnetic induction based on this electromagnetic field. The current magnitude in the tested wire can then be calculated according to the induced current magnitude and the number of iron core turns in the measuring part of the current clamp meter. For this reason, current clamp meters need to be powered by batteries. When the battery runs out, it must be replaced to continue measuring the current magnitude in the wire being tested, which is inconvenient to use.

The present utility model intends to provide an electromagnetic energy charging clamp meter to eliminate shortcomings mentioned above.

### SUMMARY OF THE UTILITY MODEL

The present utility model relates to an electromagnetic energy charging clamp meter, and comprises an electromagnetic induction unit electrically connected to a test wire, which generates corresponding induced current according to changes in the electromagnetic field of the test wire. An automatic switching unit is electrically connected to the electromagnetic induction unit and has a measurement terminal and a charging terminal. A two-stage gear switching unit is electrically connected to the measurement terminal of the automatic switching unit and has a low-range measurement and a high-range measurement. An AC/DC conversion unit is electrically connected to the two-stage gear switching unit so as to convert the AC voltage from the two-stage gear switching unit into DC voltage. A microprocessor calculation unit is electrically connected to the AC/DC conversion unit to receive the output from the AC/DC conversion unit and has a charging control output device and a measurement control output device. The charging control output device is electrically connected to the automatic switching unit, and the measurement control output device is electrically connected to the two-stage gear switching unit. A rectification unit is electrically connected to the charging terminal of the automatic switching unit so as to rectify the AC voltage from the automatic switching unit into DC voltage. An energy storage unit is electrically connected to the rectification unit so as to receive the DC voltage from the rectification unit, convert it into a fixed voltage and store it in a charging unit. A rechargeable battery is electrically connected to the charging unit so as to receive the fixed voltage from the charging unit and provide power to the microprocessor calculation unit through a DC/DC conversion unit.

The primary object of the present utility model is to provide an electromagnetic energy charging clamp meter that can automatically switch between a charging mode or a measurement mode based on whether its own power level is sufficient.

The present utility model will become more obvious from the following description when taken in connection with the accompanying drawings which show, for purposes of illustration only, a preferred embodiment in accordance with the present utility model.

### BRIEF DESCRIPTION OF THE DRAWINGS

FIG. 1 is a block diagram of the circuit of the electromagnetic energy charging clamp meter of the utility model;

FIG. 2 is a circuit schematic diagram (1) of the utility model;

FIG. 3 is a circuit schematic diagram (2) of the utility model;

FIG. 4 is a circuit schematic diagram (3) of the utility model;

FIG. 5 is a circuit schematic diagram (4) of the utility model;

FIG. 6 is a circuit schematic diagram (5) of the utility model;

FIG. 7 is a circuit schematic diagram (6) of the utility model;

FIG. 8 is a circuit schematic diagram (7) of the utility model;

FIG. 9 is a circuit schematic diagram (8) of the utility model;

FIG. 10 is a circuit schematic diagram of the utility model, showing a low-range measurement, a high-range measurement, and a control unit according to FIG. 2;

FIG. 11 is a circuit schematic diagram of the utility model, showing the charging control output device and the measurement control output device according to FIG. 4;

FIG. 12 is a schematic diagram of the utility model, in which the energy charging clamp meter measures the test wire and is signal-connected to a first external electronic device and a second external electronic device.

### DETAILED DESCRIPTION OF THE PREFERRED EMBODIMENT

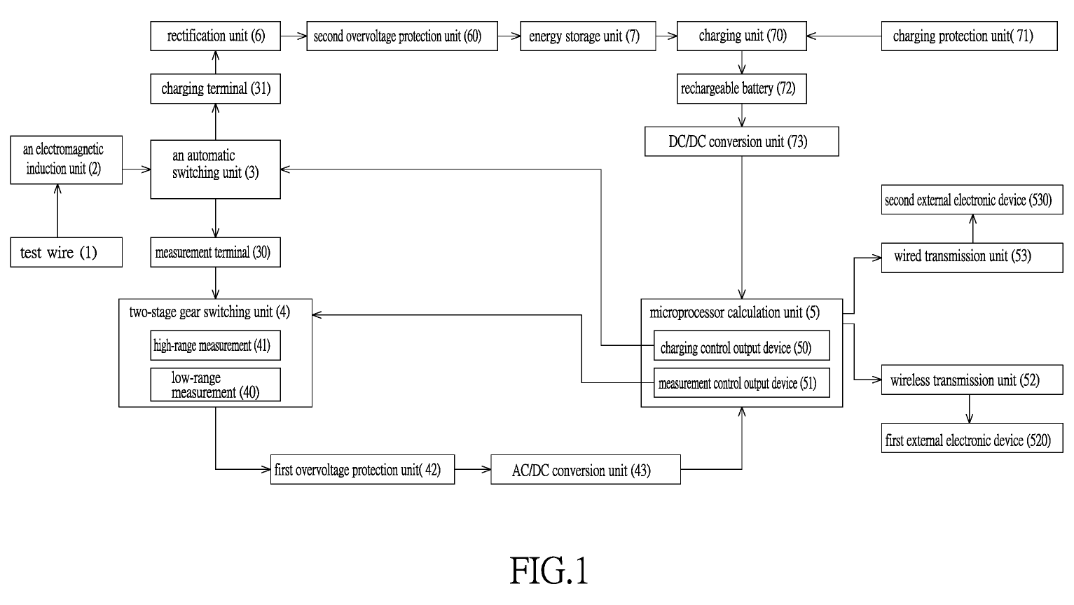

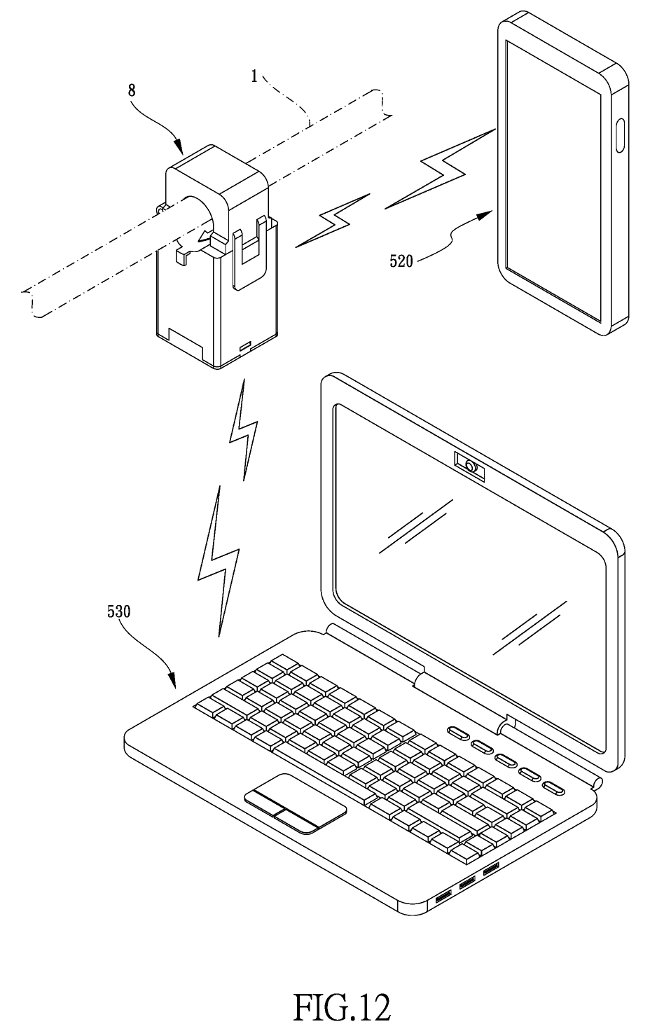

Referring to FIGS. 1 and 12, the utility model is an electromagnetic energy charging clamp meter 8 used for measuring current magnitude of a test wire 1, and comprises an electromagnetic induction unit 2, used for sensing the magnitude of the electromagnetic field of the test wire 1, and generating corresponding induced current according to changes in the electromagnetic field magnitude.

An automatic switching unit 3 is electrically connected to the electromagnetic induction unit 2 and has a measurement terminal 30 and a charging terminal 31. To avoid affecting measurement accuracy, the electromagnetic energy charging clamp meter 8 must have sufficient power when measuring the induced current of the test wire 1. Therefore, when the power level of the electromagnetic energy charging clamp meter 8 is sufficient, the automatic switching unit 3 automatically switches to the measurement terminal 30 to form an electrical connection, measuring the induced current of the test wire 1. When the power level of the electromagnetic energy charging clamp meter 8 is insufficient, the automatic switching unit 3 automatically switches to the charging terminal 31 to form an electrical connection for charging.

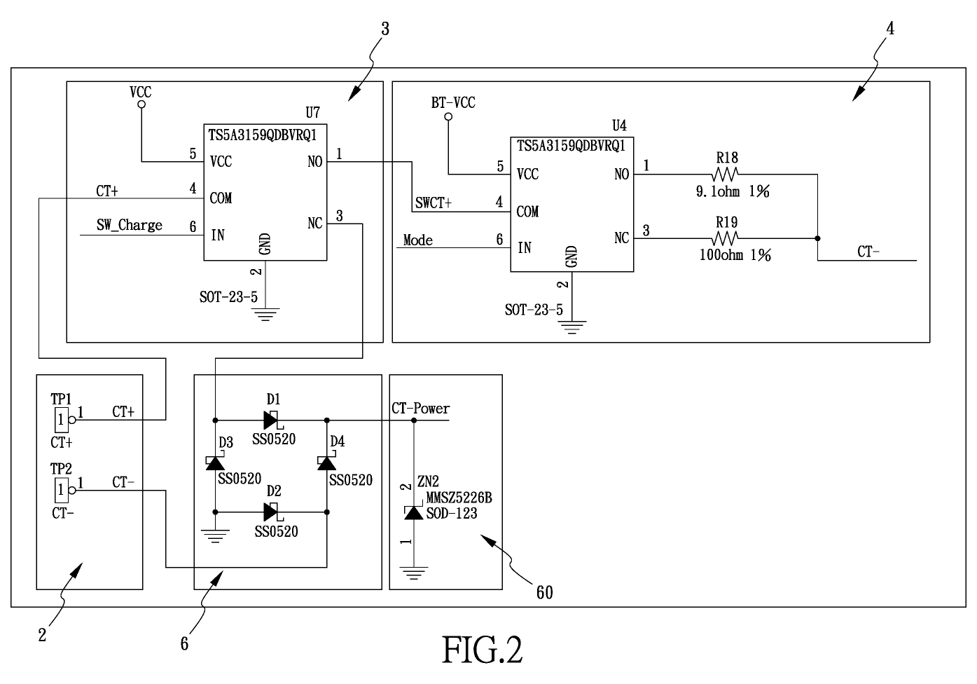

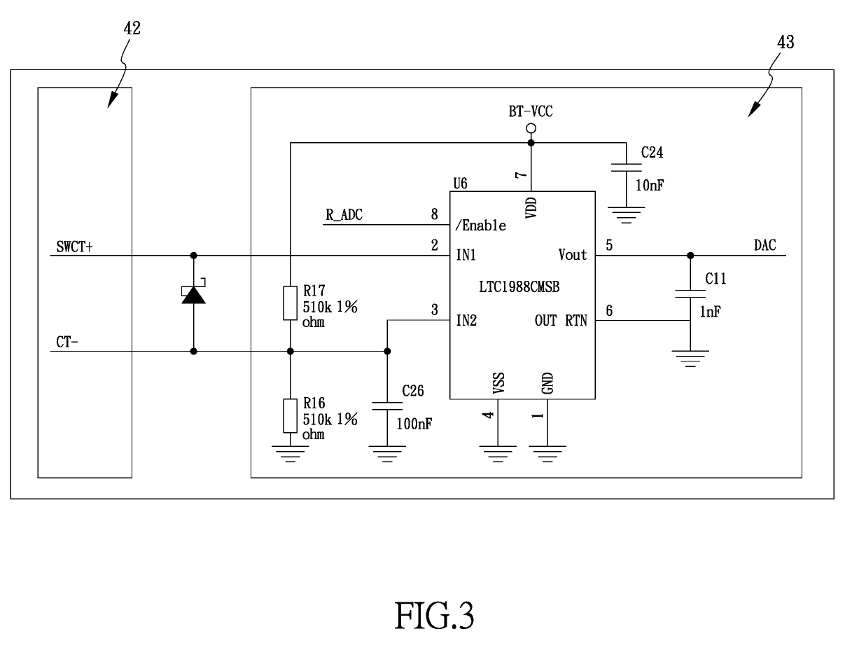

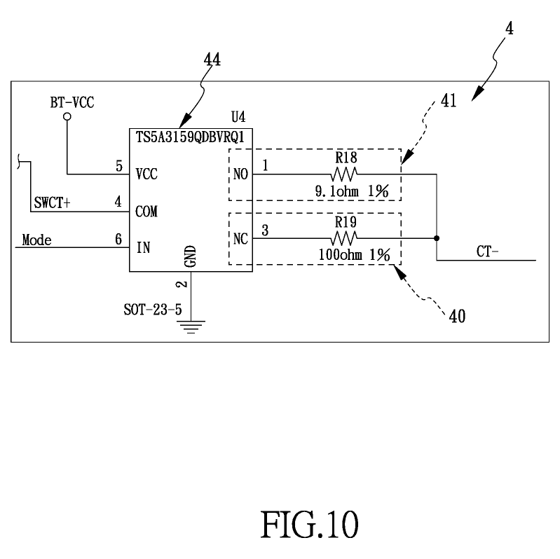

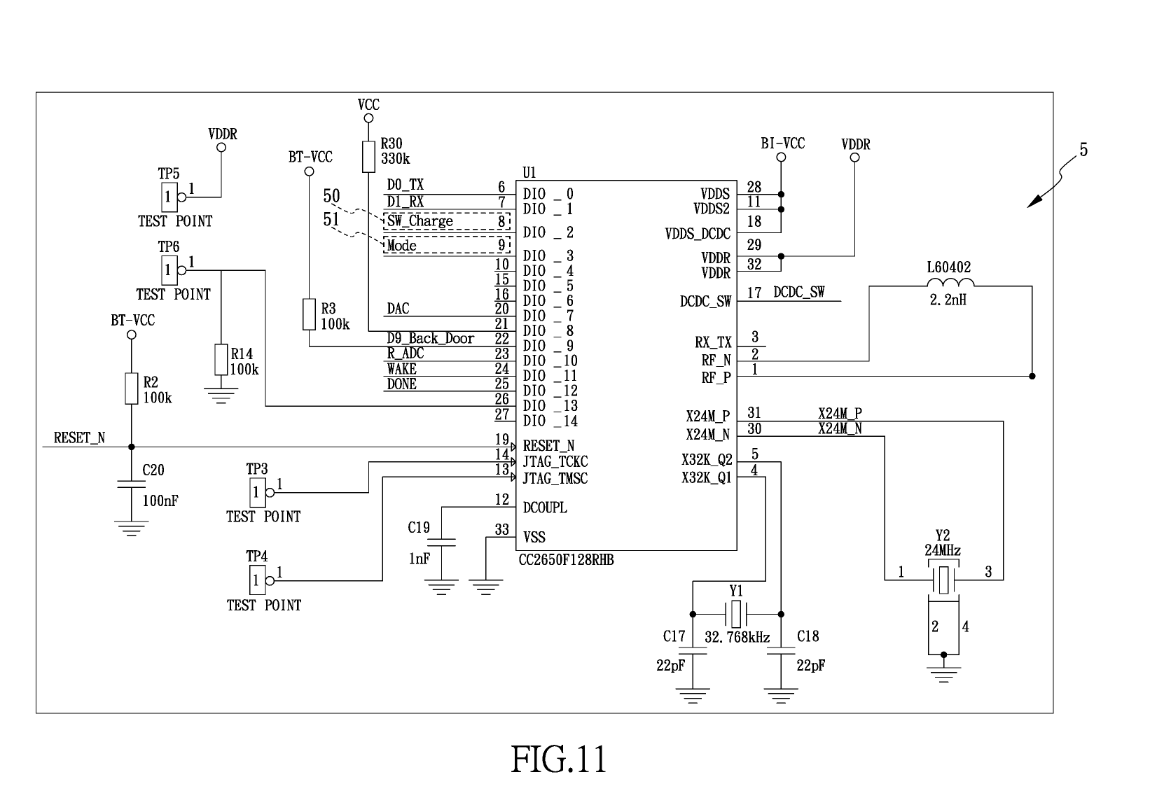

A two-stage gear switching unit 4 is electrically connected to the measurement terminal 30 of the automatic switching unit 3, and includes a low-range measurement 40, a high-range measurement 41, and a control unit 44 that are electrically interconnected, as shown in FIGS. 2 and 10. Specifically, the electromagnetic energy charging clamp meter 8 has a preset load voltage (for example: 3 volts). When the two-stage gear switching unit 4 receives a load voltage of the test wire 1, the control unit 44 determines the magnitude of the load voltage of the test wire 1. If the load voltage is less than 3 volts, the control unit 44 controls the low-range measurement 40 to be turned on for measurement. If the load voltage is greater than 3 volts, the control unit 44 controls the high-range measurement 41 to be turned on for measurement.

A first overvoltage protection unit 42 is electrically connected to the two-stage gear switching unit 4. When the AC voltage of the two-stage gear switching unit 4 has not exceeded the critical voltage value, the first overvoltage protection unit 42 outputs AC voltage normally. When the AC voltage of the two-stage gear switching unit 4 exceeds the critical voltage value, the first overvoltage protection unit 42 discharges, protecting the two-stage gear switching unit 4 from being burned out by excessive AC voltage.

An AC/DC conversion unit 43 is electrically connected to the overvoltage protection unit 42 so as to convert the AC voltage from the two-stage gear switching unit 4 into DC voltage.

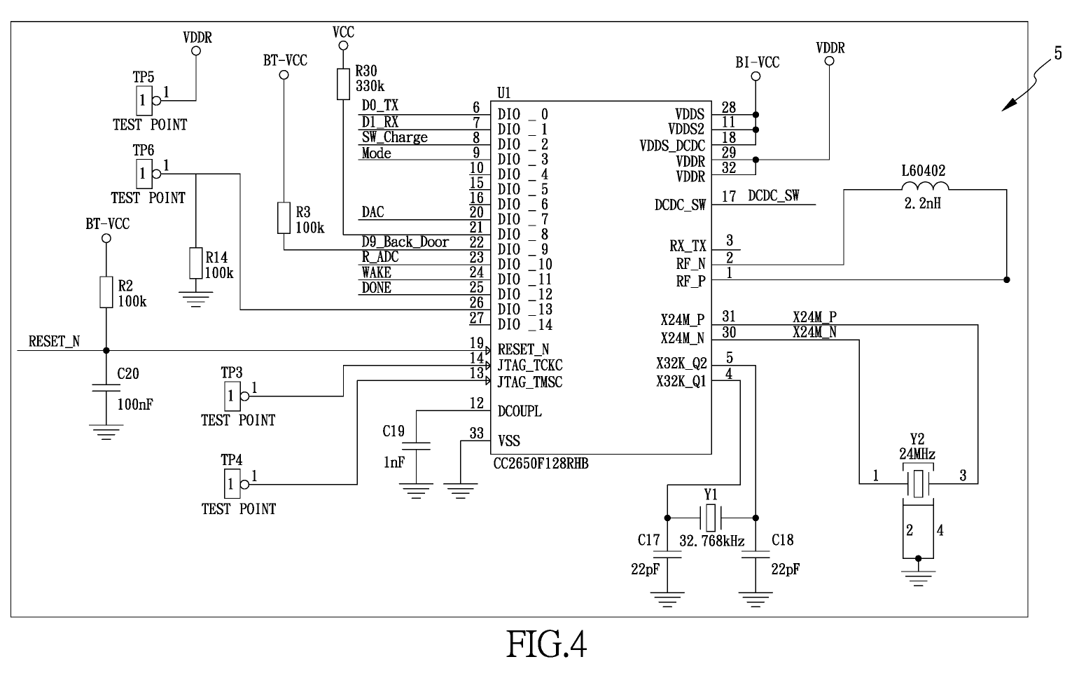

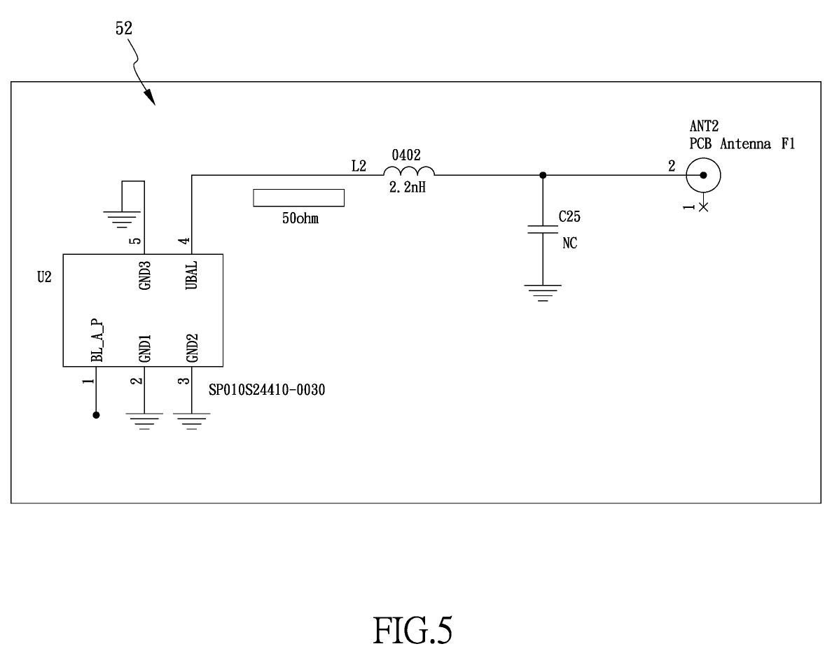

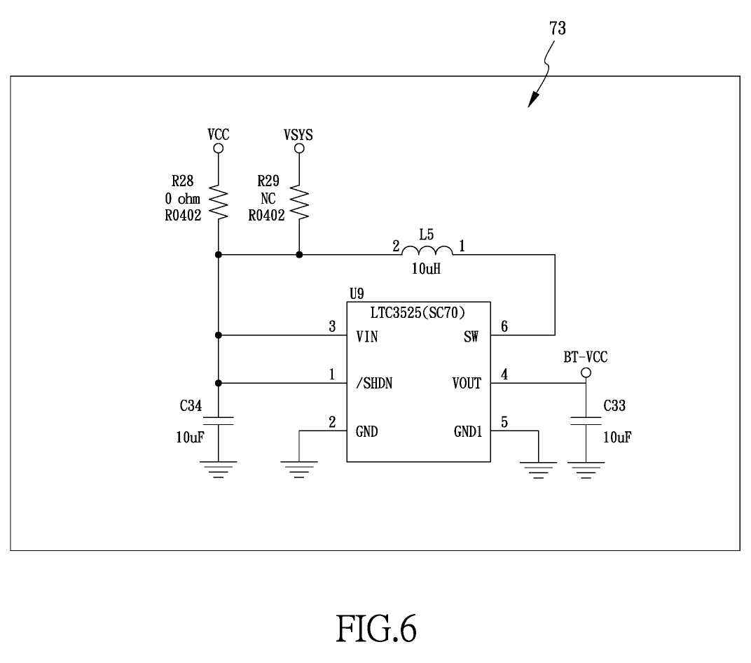

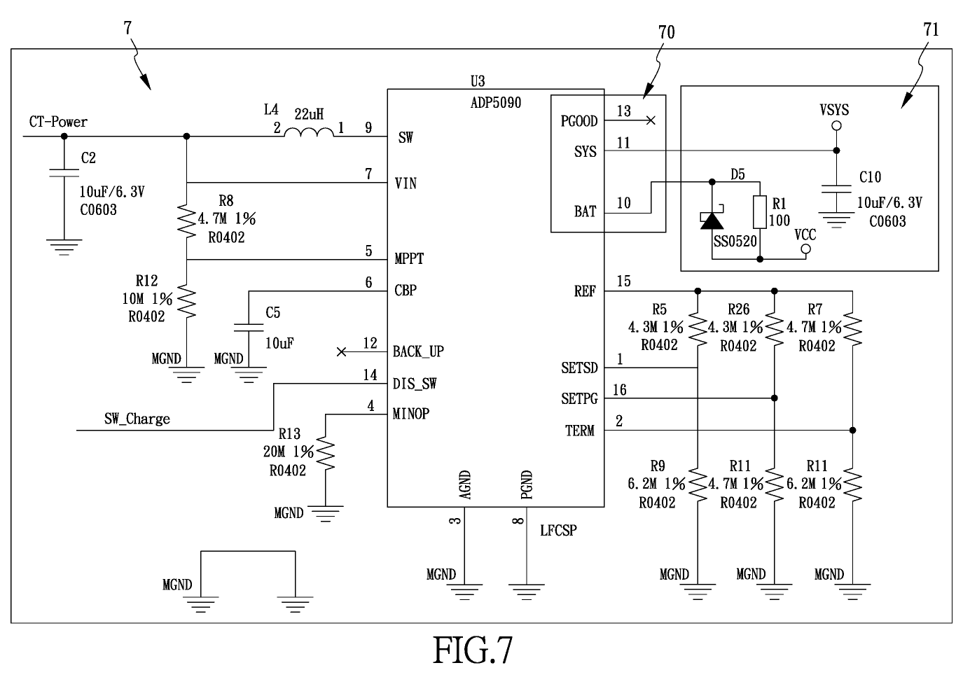

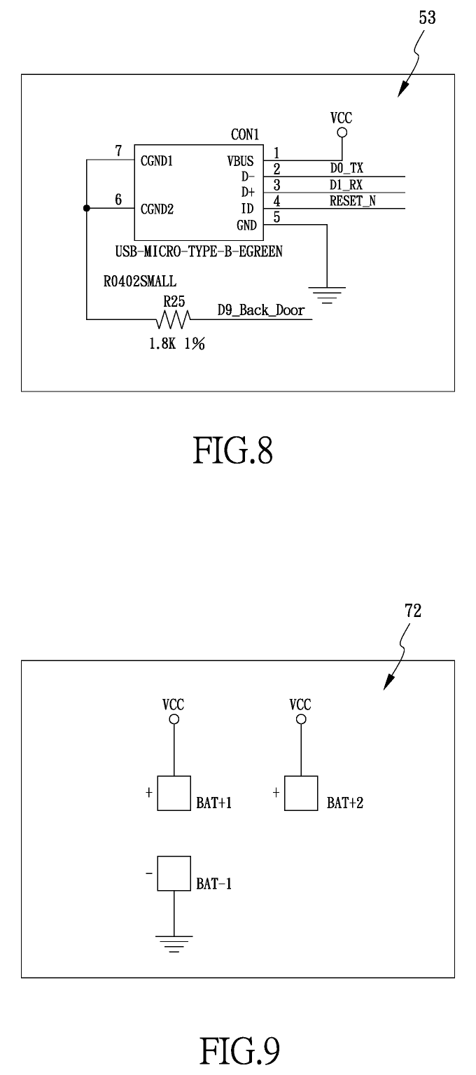

A microprocessor calculation unit 5 is electrically connected to the AC/DC conversion unit 43 to receive the DC voltage from the AC/DC conversion unit 43 and calculate the current value of the induced current based on its own conduction resistance value, then further calculate the current value corresponding to the electromagnetic field (that is, the current magnitude flowing through the test wire 1). In this embodiment, the microprocessor calculation unit 5 includes a charging control output device 50 and a measurement control output device 51. As shown in FIG.4 and FIG.10, where the charging control output device 50 is electrically connected to the automatic switching unit 3, and the measurement control output device 51 is electrically connected to the two-stage gear switching unit 4. Additionally, the microprocessor calculation unit 5 is electrically connected to a wireless transmission unit 52 and a wired transmission unit 53. The wireless transmission unit 52 receives the current magnitude of the test wire 1 calculated by the microprocessor calculation unit 5, and converts the current magnitude into a wireless signal according to a wireless communication protocol before transmitting it to a first external electronic device 520 (such as laptops, mobile phones, and other communication devices). In this embodiment, the wireless communication protocol can be ZigBee or Bluetooth Low Energy (BLE). The wired transmission unit 53 receives the current magnitude of the test wire 1 calculated by the microprocessor calculation unit 5 and transmits it as a wired signal to a second external electronic device 530 (such as a USB storage device).

A rectification unit 6 is electrically connected to the charging terminal 31 of the automatic switching unit 3 to rectify the AC voltage from the automatic switching unit 3 into DC voltage.

A second overvoltage protection unit 60 is electrically connected to the rectification unit 6 so as to protect the rectification unit 6 from being burned out by excessive AC voltage.

An energy storage unit 7 is electrically connected to the second overvoltage protection unit 60 to receive the DC voltage from the rectification unit 6 and convert it into a fixed voltage stored in the charging unit 70. The charging unit 70 is also electrically connected to the charging protection unit 71 and the rechargeable battery 72. The charging protection unit 71 provides overcharge and over-discharge protection to the charging unit 70 so as to prevent the charging unit 70 from overcharging or over-discharging. The rechargeable battery 72 receives the fixed voltage from the charging unit 70 and provides power to the microprocessor calculation unit 5 through the DC/DC conversion unit 73.

When in use, the automatic switching unit 3 automatically switches to a measurement mode or a charging mode according to the power level of the electromagnetic energy charging clamp meter 8. When the power level of the electromagnetic energy charging clamp meter 8 is sufficient, the automatic switching unit 3 switches to the measurement mode and carries out measurement operations through the measurement terminal 30 which is electrically connected to the two-stage gear switching unit 4 and the measurement control output device 51 of the microprocessor calculation unit 5 to measure the current magnitude of the test wire 1.

In this embodiment, the two-stage gear switching unit 4 selects between the low-range measurement 40 and the high-range measurement 41 according to the load voltage magnitude of the test wire 1. When the power level is insufficient, the automatic switching unit 3 switches to the charging mode and performs charging operations through the charging terminal 31, which is electrically connected to the rectification unit 6 and the charging control output device 50 of the microprocessor calculation unit 5. In this embodiment, after the rectification unit 6 rectifies the AC voltage from the test wire 1 into DC voltage, the energy storage unit 7 converts the DC voltage into a fixed voltage and stores it in the charging unit 70, providing the charging unit 70 with sufficient power to supply the microprocessor calculation unit 5. This allows the electromagnetic energy charging clamp meter 8 to measure the current of the test wire 1 without frequently replacing batteries, achieving the environmental protection effect of reducing waste battery production.

Based on the above description, the charging clamp meter of the present utility model can achieve charging effect through the current value of the test wire 1, and can automatically determine whether its own power level is sufficient. Through the automatic switching unit 3, it automatically switches to the charging mode or the measurement mode, allowing the electromagnetic energy charging clamp meter 8 to perform charging operations when the power level is insufficient and perform measurement operations when the power level is sufficient.

While we have shown and described the embodiment in accordance with the present utility model, it should be clear to those skilled in the art that further embodiments may be made without departing from the scope of the present utility model.

What is claimed is:

1. An electromagnetic energy charging clamp meter for inducing current from a test wire, comprising:
an electromagnetic induction unit (2) electrically connected to a test wire (1) which generates a corresponding induced current according to changes in an electromagnetic field of the test wire (1);
an automatic switching unit (3) electrically connected to the electromagnetic induction unit (2) and having a measurement terminal (30) and a charging terminal (31);
a two-stage gear switching unit (4) electrically connected to the measurement terminal (30) of the automatic switching unit (3) and having a low-range measurement (40) and a high-range measurement (41);
an AC/DC conversion unit (43) electrically connected to the two-stage gear switching unit (4) so as to convert the AC voltage from the two-stage gear switching unit (4) into DC voltage;
a microprocessor calculation unit (5) electrically connected to the AC/DC conversion unit (43) so as to receive an output from the AC/DC conversion unit (43) and having a charging control output device (50) and a measurement control output device (51), where the charging control output device (50) is electrically connected to the automatic switching unit (3), and the measurement control output device (51) is electrically connected to the two-stage gear switching unit (4);
a rectification unit (6) electrically connected to the charging terminal (31) of the automatic switching unit (3) so as to rectify the AC voltage from the automatic switching unit (3) into DC voltage;
an energy storage unit (7) electrically connected to the rectification unit (6) so as to receive the DC voltage from the rectification unit (6) and convert the received DC voltage into a fixed voltage and store fixed voltage in a charging unit (70), and
a rechargeable battery (72) electrically connected to the charging unit (70) so as to receive the fixed voltage from the charging unit (70) and provide power to the microprocessor calculation unit (5) through a DC/DC conversion unit (73).

2. The electromagnetic energy charging clamp meter as claimed in claim 1, wherein when a power level of the electromagnetic energy charging clamp meter is sufficient, the automatic switching unit (3) automatically switches to the measurement terminal (30) to measure the induced current of the test wire (1), when the power level of the electromagnetic energy charging clamp meter is insufficient, the automatic switching unit (3) automatically switches to the charging terminal (31) to perform charging.

3. The electromagnetic energy charging clamp meter as claimed in claim 1, wherein the electromagnetic energy charging clamp meter has a preset load voltage, when the load voltage of the test wire (1) is less than the load voltage of the electromagnetic energy charging clamp meter, the two-stage gear switching unit (4) switches to the low-range measurement (40), when the load voltage of the test wire (1) is greater than the load voltage of the electromagnetic energy charging clamp meter, the two-stage gear switching unit (4) switches to the high-range measurement (41).

4. The electromagnetic energy charging clamp meter as claimed in claim 1, wherein a first overvoltage protection unit (42) is electrically connected between the rectification unit (6) and the energy storage unit (7) so as to protect the two-stage gear switching unit (4) from being burned out by excessive AC voltage.

5. The electromagnetic energy charging clamp meter as claimed in claim 1, wherein a second overvoltage protection unit (60) is electrically connected between the two-stage gear switching unit (4) and the AC/DC conversion unit (43) so as to protect the rectification unit (6) from being burned out by excessive AC voltage.

6. The electromagnetic energy charging clamp meter as claimed in claim 1, wherein the microprocessor calculation unit (5) is electrically connected to a wireless transmission unit (52) and a wired transmission unit (53) respectively, the wireless transmission unit (52) is electrically connected to a first external electronic device (520), the wired transmission unit (53) is electrically connected to a second external electronic device (530).

7. The electromagnetic energy charging clamp meter as claimed in claim 1, wherein the charging unit (70) is electrically connected to a charging protection unit (71) so as to prevent the charging unit (70) from overcharging or over-discharging.
